(19) United States
(12) Patent Application Publication
(10) Pub. No.: US 2006/0082969 A1
(43) Pub. Date: Apr. 20, 2006

(54) Alternator in connection with a remotely-cooled rectifier

(75) Inventor: Lutz Heidrich, Karlsruhe (DE)

Correspondence Address: CROWELL & MORING LLP;INTELLECTUAL PROPERTY GROUP, P.O. BOX 14300, WASHINGTON, DC, 20044-4300, US

(73) Assignee: DaimlerChrysler AG, Stuttgart (DE)

(21) Appl. No.: 10/534,129

(22) PCT Filed: Oct. 15, 2003
(86) PCT No.: PCT/EP03/11401

§ 371 Date: Nov. 4, 2005

(30) Foreign Application Priority Data
Nov. 7, 2002 (DE) 102 52 252.9

(51) Int. Cl. H05K 7/20

(52) U.S. Cl. 361/697

(57) ABSTRACT

A rectifier, which is associated with an alternating current machine of an internal combustion engine has two heat sinks each having two or more diodes. The heat sinks of the rectifier 2 are arranged physically separate from the alternating current machine, upstream and/or downstream (relative to the flow direction of the cooling air) of a cooler fan. The regulator for the rectifier is likewise arranged physically separate between the rectifier housing 7 and the alternating current machine.

### BACKGROUND AND SUMMARY OF THE INVENTION

This application claims the priority of German patent document 102 52 252.9, filed Nov. 7, 2002 (PCT International Application No. PCT/EP2003/011401, filed Oct. 15, 2003, the disclosure of which is expressly incorporated by reference herein.

The invention relates to an internal combustion engine, which has an electrical supply for a DC voltage network and an alternating current machine, which is arranged externally on the internal combustion engine. A rectifier, which electrically connects the DC voltage network and the alternating current machine has at least two heat sinks, which each have at least one associated diode and are in the form of a negative pole or positive pole.

An electrical machine or a three-phase generator with a rectifier unit is disclosed in German patent document DE 197 05 228 A1. The rectifier unit is provided on the rearward face of the end frame, with the positive or negative heat sink together with the positive and negative diodes. The latter are connected to a circuit board with the interposition of an insulating panel, like a sandwich. The heat sink has two or more cooling openings for a cooling flow which is produced by the fan of the machine, and at least some of the cooling openings are provided with cooling ribs.

One object of the present invention is to provide a three-phase machine for an internal combustion engine which ensures optimum cooling of the rectifier.

This and other objects and advantages are achieved by the apparatus according to the invention, in which at least the heat sink of the rectifier is arranged physically separately from the alternating current machine. The heat sink is provided in the area of a fan, and has an associated fan. This means that the rectifier can be optimally cooled independently of the particular power class. The physical space which is available on the internal combustion engine can be optimally utilized for the alternating current machine. Furthermore, the cooling power which is provided on the alternating current machine is available for the alternating current machine. In this case, the fan may be an existing cooler fan, or an additional, external fan.

For this purpose, it is advantageous for the rectifier to have an associated regulator arranged between the heat sink and the alternating current machine, on a frame part or frame longitudinal support of the internal combustion engine. The regulator is provided with a separate electrical coupling, so that it need not be arranged immediately adjacent to the rectifier or to the alternating current machine.

According to one embodiment of the invention, the fan is in the form of a cooler fan, and has a rotation speed that is dependent on the DC voltage network voltage, such that it generates an increase in rotation speed if the DC voltage network voltage drops below a critical value, Uₘᵢₙ. Adequate cooling power for the cooler fan for the rectifier is thus ensured in the event of electrical overloading of the alternating current machine and a resulting voltage drop. The hydrostatic cooler fan is in this case driven via a bypass proportional valve. The other control parameters are the boost air temperature and coolant temperature of the internal combustion engine. The parameters are output by engine regulation as a partial voltage value of the on-board network voltage. The on-board network voltage thus represents an indirect control parameter for fan control.

It is also advantageous for the heat sink to be arranged on the rectifier housing (which is formed from plastic), via at least one spacing sleeve which is in the form of a voltage tap for the DC voltage network. The heat sink is connected to the rectifier housing by means, of plastic screws. The mechanical attachment of the heat sinks is thus optimally coupled to the electrical insulation, since the diodes are mechanically and electrically coupled to the respective heat sink.

For this purpose, it is also advantageous for the rectifier housing to be arranged in or with respect to the flow direction of the cooling air in the area of a cooler fan, with the first face, which is associated with the fan housing or the cooler fan, being open, and the second, opposite face having two or more ventilation openings for cooling air. The open first face is protected against access or damage by the cooler fan. The second face as well as the edge area of the rectifier housing are freely accessible and are provided with ventilation openings or ventilation slots in order to ensure convection. The ventilation slots are in this case aligned such that they correspond to the cooling ribs, and have a similar projection area with respect to the flow direction of the cooling air thus ensuring optimum convection and flow of the cooling air between the cooling ribs and out of the rectifier housing.

According to a preferred embodiment of the invention, provision is finally made for a cable duct to be provided between the rectifier, the regulator and/or the alternating current machine, with the cable duct being at least partially in the form of an electromagnetic screen. The relatively large alternating current in the electrical connecting line between the rectifier and the alternating current machine generates an AC voltage field, which is not uncritical and leads to radiated emission of an electromagnetic field. There is thus no need for additional screening.

According to the invention, the heat sink has two or more cooling ribs which are connected to one another and/or attached to a rectifier housing on at least one side, and are open downwards in the direction of the vertical. The open configuration can prevent the continuous accumulation of dirt, since it falls downwards. The joint connection on the upper face is used both for joint cooling and for joint potential formation, as a positive or negative pole.

In conjunction with the configuration and arrangement according to the invention, it is advantageous for the rectifier to have a power of between 2.5 kW and 3.6 kW and to be formed from at least 12 diodes, with at least two diodes in each case being connected in parallel.

It is also advantageous for the alternating current machine to be attached to the internal combustion engine together with a further unit, and to have a common drive with this further unit. This means that there is no need to redevelop the internal combustion engine or its crankcase.

It is also advantageous for the rectifier heat sink, which holds the diodes, to be arranged physically separate from the alternating current machine in the flow direction of the cooling air of a cooler fan, and in its immediate vicinity, with the rectifier housing which holds the heat sink having two or more ventilation openings, and the regulator for the rectifier being arranged physically separate between the rectifier housing and the alternating current machine.

The diodes are in this case push-in rectifier diodes, which are directly connected via a press fit to the heat sink, which is in the form of a positive or negative pole.

Other objects, advantages and novel features of the present invention will become apparent from the following detailed description of the invention when considered in conjunction with the accompanying drawings.

### BRIEF DESCRIPTION OF THE DRAWINGS

FIG. 1 shows a perspective rear view of the rectifier with a heat sink and diode;

FIG. 2 shows an illustration 6f part of the installed rectifier, in the area of a cooler fan;

FIG. 3 shows a perspective illustration of the rectifier housing.

### DETAILED DESCRIPTION OF THE DRAWINGS

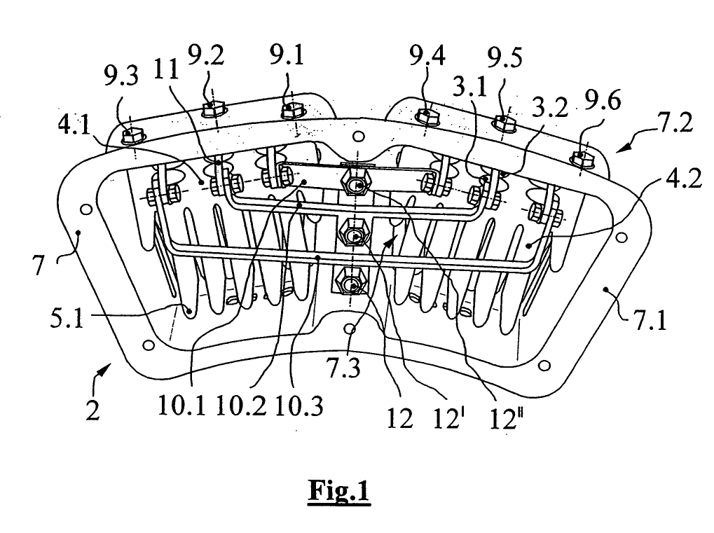

A rectifier housing 7 as shown in FIG. 1 is used to hold first and second heat sinks 4.1 and 4.2, which are each fitted with two diodes 3.1, 3.2 that rectifies the applied AC voltage. The two diodes 3.1, 3.2 are electrically connected via a busbar 11, with the various busbars 11 likewise being electrically connected via three current links 10.1-10.3. The current links 10.1-10.3 are each attached to the rectifier housing 7 via a holding screw 12, which is used as an electrical power connection.

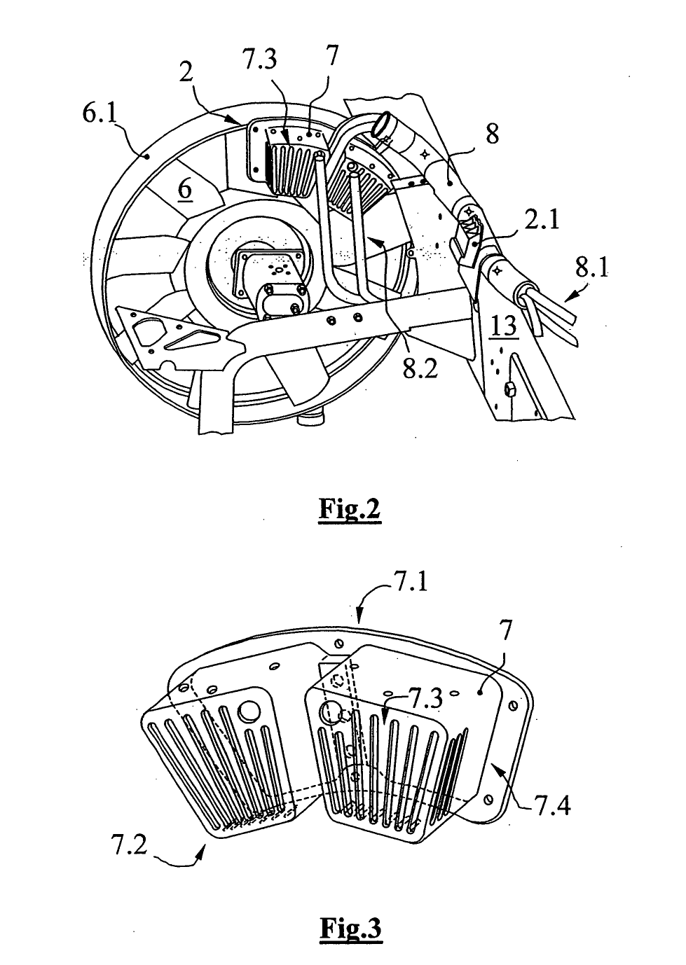

The heat sinks 4.1, 4.2 have two or more cooling ribs 5.1 which, as shown in FIG. 1, are connected at their upper end, which holds the diodes 3.1, 3.2, and are in the form of laminates in the downward direction. The laminates are open at their lower end. The heat sinks 4.1, 4.2 are mechanically connected to the rectifier housing 7 via two or more plastic screws 9.1 to 9.6. The rectifier housing 7 is open on a first face 7.1, which is aligned forwards in this case, with this open first face 7.1, as shown in FIG. 2, facing a cooler fan housing 6.1 or a cooler fan 6 in the installed state.

A second face 7.2, which is illustrated at the rear in FIG. 1, has two or more ventilation openings 7.3, which are arranged in the form of slots, parallel to one another. The ventilation openings 7.3 are aligned substantially vertically, as shown in FIG. 1, matched to the cooling ribs 5.1. In addition, the rectifier housing 7 has further cooling openings on its lower face, opposite the plastic screws 9.1 to 9.6.

As can be seen from FIG. 2, the rectifier housing 7 is screwed by its first face 7.1 to the cooler fan housing 6.1. The rectifier housing 7 is in this case arranged behind the cooler fan 6 with respect to the cooling air flow direction, so that the cooling air which is flowing through the cooler fan 6 passes through the rectifier housing 7, and thus through the heat sinks 4.1, 4.2, which are like laminates.

The current links 10.1-10.3 and the holding screws 7.3 are connected to the alternating current machine via the electrical connecting cable 8.1. The regulator 2.1 is directly electrically connected to the alternating current machine, which is arranged on the internal combustion engine, via a cable which is not illustrated. Furthermore, the heat sinks 4.1, 4.2, or the positive pole and the negative pole, are electrically connected to the DC voltage network of the internal combustion engine.

The cooler fan 6 is in this case attached directly to the frame longitudinal support 13 in the area of a coolant cooler, which is driven hydrostatically (not illustrated). At least some of the cables 8.1 between a rectifier 2 or the positive and negative pole and the alternating current machine, (not illustrated) are arranged in a cable duct 8, which forms an electromagnetic screen for the cables 8.1.

As can be seen from FIG. 3, the rectifier housing 7 is kidney-shaped or in the form of part of a circle, corresponding to the circular shape of the cooler fan 6. In addition to the ventilation openings 7.3 on the second face 7.2, the rectifier housing 7 has additional ventilation openings on the outer side surface 7.4.

The rectifier housing 7 in this case forms a specific housing chamber for each heat sink 4.1, 4.2, so that the two heat sinks 4.1, 4.2 which form the positive pole and negative pole are electrically separated and isolated.

The alternating current machine is attached to the internal combustion engine via a cast combination support (not illustrated), together with a hydraulic pump for a hydrostatic fan. The pulley disc for the alternating current machine in this case has an effective diameter of 81 mm, thus resulting in a step-up ratio i between the internal combustion engine and the alternating current machine of about i=0.34.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1.-10. (canceled)

11. Electrical supply apparatus for an internal combustion engine which has a DC voltage network and an alternating current machine arranged externally on the internal combustion engine said apparatus comprising:
rectifier which electrically connects the DC voltage network and the alternating current machine; wherein,
the rectifier has at least two heat sinks, which each have at least one associated diode and are in the form of a negative pole or positive pole;
at least one of said heat sinks is arranged physically separate from the alternating current machine;
the at least one of said heat sinks has an associated fan, and is arranged via at least one spacing sleeve on a rectifier housing which is formed from plastic; and
the spacing sleeve is in the form of a voltage tap for the DC voltage network.

12. Apparatus according to claim 11, wherein the rectifier has an associated regulator arranged between said at least one of the heat sinks and the alternating current machine, on a frame part of the internal combustion engine.

13. Apparatus according to claim 11, wherein:
the fan is in the form of a cooler fan, and has a rotation speed that is dependent on the DC voltage network voltage; and
the cooler fan increases in rotation speed if the DC voltage network voltage drops below a critical value, Uₘᵢₙ.

14. Apparatus according to claim 11, wherein the heat sink is connected to the rectifier housing via at least one plastic screw.

15. Apparatus according to claim 11, wherein:
the rectifier housing is arranged in a flow direction of cooling air in the vicinity of a cooler fan;
at least one first face of the housing associated with the cooler fan is open; and
a second, opposite face of the housing has at least two ventilation openings for cooling air.

16. Apparatus according to claim 11, wherein:
a cable duct is provided between the rectifier and the alternating current machine; and
the cable duct is at least partially in the form of an electromagnetic screen.

17. Apparatus according to claim 11, wherein said at least one of the heat sink has at least two cooling ribs that are connected to one another or are attached to a rectifier housing of the rectifier on at least one side; and
the cooling ribs are open vertically downwards.

18. Apparatus according to claim 11, wherein:
the rectifier has a power of between 2.5 kW and 3.6 kW and comprises at least 12 diodes; and
at least two diodes in each case are connected in parallel.

19. Apparatus according to claim 11, wherein the alternating current machine is attached, together with a further unit, to the internal combustion engine, and has a common drive with the further unit.

20. Apparatus according claim 12, wherein said at least one of the heat sinks is arranged upstream and/or downstream of the fan relative to a flow direction of cooling air; and
the rectifier housing has at least two ventilation openings.

21. Apparatus according to claim 12, wherein:
a cable duct is provided between the rectifier, the regulator and/or the alternating current machine; and
at least part of the cable duct forms an electromagnetic screen.
